(19) United States
(12) Patent Application Publication
(10) Pub. No.: US 2011/0042558 A1
(43) Pub. Date: Feb. 24, 2011

(54) Optical device and method of manufacturing the same

(75) Inventors: Terukazu Naruse, Kanagawa (JP); Takahiro Arakida, Kanagawa (JP); Hidehiko Nakata, Miyagi (JP); Yuji Masui, Kanagawa (JP); Naoki Jogan, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/805,494

(22) Filed: Aug. 3, 2010

(30) Foreign Application Priority Data
Aug. 21, 2009 (JP) 2009-192121

(51) Int. Cl. H01L 31/12; H01L 31/0203; B05D 3/06

(52) U.S. Cl. 250/239; 427/553

(57) ABSTRACT

An optical device and a method of making an optical device is described herein. The optical device comprises a housing, an optical element, a base structure that supports the optical element and that interfaces with the housing to form a gap section between an outer wall section of the base structure and an inner wall section of the housing, a resin within the gap section fixing the housing to the base structure, and a light accommodation section in the housing. The light accommodation section accommodates a transmittance of light to the resin within the gap section.

### BACKGROUND OF THE INVENTION

1. Field of the Invention

The present invention relates to an optical device having a light transmission function converting an electric signal into a light signal and outputting the light signal, or a light reception function converting a light signal into an electric signal and outputting the electric signal, and relates to a method of manufacturing the optical device.

2. Description of Related Art

In a module, according to an XFP (10-Gibabit Small Form Factor Pluggable) as a standard for light transmitter/receiver modules, an optical device, which includes a light transmitter device that converts an electric signal into a light signal and outputs the light signal or a light receiver device that converts a light signal into an electric signal and outputs the electric signal, is mounted. In such an optical device, for example, a light emitting element or a light receiving element is mounted on a top of a stem (header) and sealed by a cap, and furthermore, a lens receptacle (barrel) for optical coupling between the light emitting element or the light receiving element and an optical fiber is bonded to the cap (for example, see U.S. Pat. No. 7,476,905).

### SUMMARY OF THE INVENTION

An optical device and a method of making an optical device is described herein.

By way of example, the optical device comprises a housing, an optical element, a base structure that supports the optical element and that interfaces with the housing to form a gap section between an outer wall section of the base structure and an inner wall section of the housing, a resin within the gap section fixing the housing to the base structure, and a light accommodation section in the housing that accommodates a transmittance of light to the resin within the gap section.

### BRIEF DESCRIPTION OF THE DRAWINGS

FIG. 1 is a perspective view of a light transmitter device according to an embodiment of the invention.

FIG. 2 is a section view of the light transmitter device of FIG. 1.

FIG. 3 is a section view showing an example of a light accommodation section in FIG. 1.

FIG. 4 is a section view showing a first modification of the light accommodation section in FIG. 1.

FIG. 5 is a section view showing a second modification of the light accommodation section in FIG. 1.

FIG. 6 is a section view showing a third modification of the light accommodation section in FIG. 1.

FIG. 7 is a section view showing a fourth modification of the light accommodation section in FIG. 1.

FIG. 8 is a section view showing a fifth modification of the light accommodation section in FIG. 1.

FIG. 9 is a section view showing a sixth modification of the light accommodation section in FIG. 1.

FIG. 10 is a section view showing a seventh modification of the light accommodation section in FIG. 1.

FIG. 11 is a section view for illustrating an example of a method of manufacturing the light transmitter device of FIG. 1.

FIG. 12 is a section view for illustrating a step following a step of FIG. 11.

FIG. 13 is a section view of a modification of the light transmitter device of FIG. 1.

FIG. 14 is a section view of a light receiver device.

FIG. 15 is a section view of a modification of the light receiver device of FIG. 14.

### DETAILED DESCRIPTION OF THE PREFERRED EMBODIMENTS

In the optical device, a UV curing resin has been used in the past for bonding between a lens receptacle and a cap. However, a gap between the lens receptacle and the cap is extremely narrow, and therefore the resin has to enter a limited space between a lower end of the receptacle and the cap. This has led to a lens receptacle fluctuation occurring after temporary fixing the lens receptacle to the cap, and alignment of the lens receptacle. Thus, U.S. Pat. No. 7,476,905 proposes use of a capillary action to allow the UV curing resin to penetrate deep into the gap.

However, the lens receptacle material hardly transmits UV light because of various restrictions. Therefore, even if the UV curing resin is allowed to penetrate deep into the gap, a long time is required for curing the UV curing resin that has penetrated deep into the gap, which leads to an extremely low throughput. Thus, when only the UV curing resin near a lower end of the lens receptacle is cured to reduce time for temporary fixing, lens receptacle fluctuation is not improved.

It is desirable to provide an optical device that may suppress fluctuation of the lens receptacle while reduction in throughput is minimized, and provide a method of manufacturing the optical device.

A first optical device of an embodiment of the invention comprises a housing, an optical element, a base structure that supports the optical element and that interfaces with the housing to form a gap section between an outer wall section of the base structure and an inner wall section of the housing, a resin within the gap section fixing the housing to the base structure, and a light accommodation section in the housing that accommodates a transmittance of light to the resin within the gap section.

A second optical device of an embodiment of the invention comprises a housing, an optical element, a base structure that supports the optical element and that interfaces with the housing to form a gap section between an outer wall section of the base structure and an inner wall section of the housing, a resin within the gap section fixing the housing to the base structure, and a light accommodation section. The light accommodation section and the gap section separately expose the resin to light such that either exposed resin portion or both are irradiated to temporarily fix the housing over the base.

In the first and second optical devices, a light accommodation section that accommodates a large light transmittance is provided in the housing. Thus, in the case that an uncured adhesion section is irradiated with light from the outside during a manufacturing process, a portion exposed to the outside of the uncured adhesion section and a portion corresponding to the light accommodation section of the adhesion section may be efficiently irradiated with external light.

A first method of manufacturing an optical device of an embodiment of the invention comprises applying a resin to an outer wall section of a base, spreading the resin by placing a housing over the base such that the resin fills a gap portion between an inner wall section of the housing and the outer wall section of the base; and irradiating with light the resin through a light accommodation section in the housing to fix the housing over the base.

A second method of manufacturing an optical device of an embodiment of the invention comprises applying a resin to an outer wall section of a base, spreading the resin by placing a housing over the base such that the resin fills a gap portion between an inner wall section of the housing and the outer wall section of the base, irradiating with light the resin through either a light accommodation section in a housing, the gap portion, or both to temporarily fix the housing over the base; and heating the resin to permanently fix the housing over the base.

In the first and second methods of manufacturing an optical device, the housing is fitted with the base or the sealing section such that a UV curing resin enters a gap between the circumferential surface of the base and the housing or a gap between the circumferential surface of the sealing section and the housing. Thus, the UV curing resin can penetrate deep into the gap without using a capillary action. In the embodiment of the invention, since the UV curing resin is adhered to the circumferential surface of the base or the sealing section, viscosity of the a UV curing resin is high compared with viscosity of the UV curing resin in the case of using the capillary action. Therefore, even if the UV curing resin is not irradiated with a UV light for a long time, the UV curing resin may be cured over a wide range.

According to the first and second optical devices, in the case that an uncured adhesion section is irradiated with light from the outside during a manufacturing process, a portion exposed to the outside of the uncured adhesion section and a portion corresponding to the light accommodation section of the adhesion section may be efficiently irradiated with external light. Thus, fluctuation may be suppressed while reduction in throughput is minimized.

According to the first and second methods of manufacturing an optical device of the embodiment of the invention, the UV curing resin may be allowed to penetrate deep into the gap without using the capillary action. Thus, fluctuation may be suppressed while reduction in throughput is minimized.

Other and further objects, features and advantages of the invention will appear more fully from the following description.

Hereinafter, a preferred embodiment of the invention will be described in detail with reference to drawings.

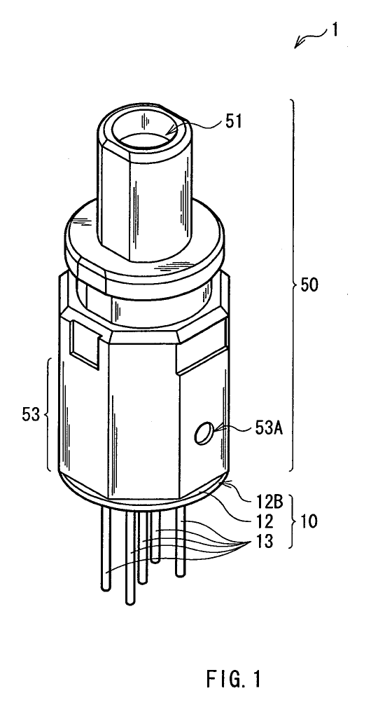

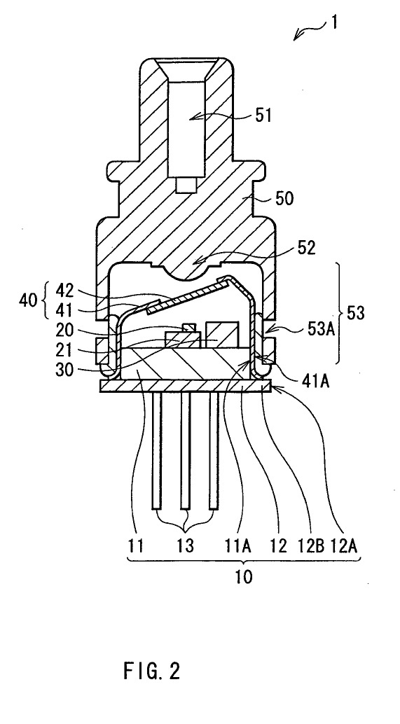

FIG. 1 perspectively illustrates a schematic configuration of a light transmitter device 1 according to an embodiment of the invention. FIG. 2 illustrates a sectional configuration of the light transmitter device of FIG. 1. FIGS. 1 and 2 schematically show the configurations, and may be different in size or shape from actual invention.

The light transmitter device 1 according to the embodiment, which is generally called TOSA (Transmitter Optical SubAssembly), converts an externally inputted electric signal into an optical signal and outputs the optical signal. The light transmitter device 1 includes, for example, a stem 10, a light emitting element 20, a light receiving element 30, a cap 40, and a lens receptacle 50. The stem 10 corresponds to a specific example of “base” of the invention. The light emitting element 20 corresponds to a specific example of “optical element” of the invention. The light receiving element 30 also corresponds to a specific example of “optical element” of the invention. The cap 40 corresponds to a specific example of “sealing section” of the invention, and the lens receptacle 50 corresponds to a specific example of “optical coupling section” of the invention.

The stem 10 configures a package of the light transmitter device 1 in conjunction with the lens receptacle 50, and, for example, has a support substrate 11 supporting the light emitting element 20, an outer frame substrate 12 disposed on a back of the support substrate 11, and a plurality of connection terminals 13. The support substrate 11 and the outer frame substrate 12 have, for example, a disk shape each, and are disposed such that central axes (not illustrated) of both substrates corresponds to each other. A side face (circumferential surface) 11A of the support substrate 11 is, for example, parallel to a normal direction of the support substrate 11. Similarly, a side face (circumferential surface) 12A of the outer frame substrate 12 is, for example, parallel to a normal direction of the outer frame substrate 12. Width of the side face 11A is, for example, larger than width of the side face 12A, so that the cap 40 or the lens receptacle 50 is easily fitted with the support substrate 11. Diameter of the outer frame substrate 12 is larger than diameter of the support substrate 11. An outer edge of the outer frame substrate 12 is formed to be an annular flange 12B hanging in a radial direction from the central axis of the outer frame substrate 12 in a plane with the central axis of the outer frame substrate 12 as a normal. The flange 12B acts to define a reference position when the cap 40 or the lens receptacle 50 is fitted with the support substrate 11 during manufacturing. A plurality of connection terminals 13 penetrate through the support substrate 11 and the outer frame substrate 12, and, for example, project long to the outer frame substrate 12 side, and project short to the support substrate 11 side. Portions of the connection terminals 13, which project long to the outer frame substrate 12 side, correspond to, for example, portions to be fitted into a board for optical communication. In contrast, portions of the connection terminals 13, which project from the support substrate 11 side, correspond to portions to be electrically connected to the light emitting element 20 and the light receiving element 30 via wires (not illustrated) or the like. The connection terminals 13 are supported by insulating members (not illustrated) provided on the support substrate 11 and the outer frame substrate 12. The connection terminals 13 are isolated from the support substrate 11 and the outer frame substrate 12 via the above-mentioned insulating members. Furthermore, individual connection terminals 13 are isolated from one another by the above-mentioned insulating members.

The light emitting element 20 and the light receiving element 30 are mounted on a top of the support substrate 11. For example, the light emitting element 20 is mounted on the top of the support substrate 11 while being disposed on a sub-mount 21. The light emitting element 20, which converts an electric signal into an optical signal and outputs the optical signal, outputs light in a direction normal to the support substrate 11 surface (i.e. the surface where the substrate meets the optical elements). The light emitting element 20 is, for example, a vertical cavity surface emitting laser (VCSEL), and disposed such that a light axis of the light emitting element 20 is normal to the support substrate 11 surface. The light emitting element 20 is preferably disposed such that the light axis thereof corresponds to a central axis (not illustrated) of the support substrate 11. The light receiving element 30 is provided to monitor output of light outputted from the light emitting element 20. The light receiving element 30, which converts an optical signal into an electric signal and outputs the electric signal, detects light having a component in a direction normal to the support substrate 11 surface. The light receiving element 30 is, for example, a photodiode (PD), and disposed such that light (reflected light) reflected by a light transmission window 42 described later enters into a light receiving surface (not illustrated) among light outputted from the light emitting element 20. The light emitting element 20 and the light receiving element 30 may be separately configured, or integrally configured.

The cap 40 seals the light emitting element 20 and the light receiving element 30. The cap 40 has, for example, a cylindrical portion 41 having an opening in each of upper and lower ends. A lower end of the cylindrical portion 41 is contacted to a side face 11A of the support substrate 11, and the light emitting element 20 and the light receiving element 30 are located in an internal space of the cylindrical portion 41. The cap 40 has a light transmission window 42 disposed in a manner of closing the opening on an upper end side of the cylindrical portion 41. The light transmission window 42 is, for example, disposed at a position above the light emitting element 20 as illustrated in FIG. 2, and has a function of transmitting light outputted from the light emitting element 20. The light transmission window 42 further has a function of a half mirror transmitting a part of light outputted from the light emitting element 20, and reflecting another part of the light.

The lens receptacle 50 optically couples the light emitting element 20 with an optical fiber (not illustrated). The lens receptacle 50 has, for example, a sleeve 51 supporting the optical fiber, a lens 52 focusing light outputted from the light emitting element 20, an annular housing 53 facing a circumferential surface of the cap 40 (side face 41A of the cylindrical portion 41) with a predetermined gap in between. The sleeve 51 is formed in an end (upper end) of the lens receptacle 50, and has a cylindrical space 51A through which a housing of an optical fiber is removably inserted. The lens 52 is arranged coaxially with a light axis (not illustrated) of an optical fiber when the optical fiber is supported by the sleeve 51. The lens 52, which is a convex lens projecting to a light emitting element 20 side, focuses light outputted from the light emitting element 20 onto an end face of the optical fiber supported by the sleeve 51.

When an optical fiber is mounted in the sleeve 51, the lens receptacle 50 needs to be subjected to alignment described later in order to dispose an end face of the optical fiber in a place corresponding to a focal distance. Before the alignment, the lens receptacle 50 needs to be subjected to temporary fixing described later. In the embodiment, the housing 53 has a structure (light accommodation section) suitable for the temporary fixing. Hereinafter, the light accommodation section of the housing 53 will be described in detail.

The housing 53 is formed in an end (lower end) on a side opposite to a sleeve 51 side of both ends of the lens receptacle 50, and has a cylindrical space that may accommodate the support substrate 11, the light emitting element 20, and the light receiving element 30. When a light accommodation section 53A described later is not formed, the housing 53 has, for example, an n-fold, rotationally symmetric shape (n is a positive integer such as 2, 3 or 4). The housing 53 has one or multiple light accommodation sections 53A. The light accommodation section 53A is formed in part of the housing 53, and accommodates light more than other regions of the housing 53. For example, light accommodation of the light accommodation section 53A is at least ten times as large as light accommodation of the other regions of the housing 53. Here, light accommodation refers to transmittance of UV light when the housing 53 and the light accommodation section 53A are laterally irradiated with UV light.

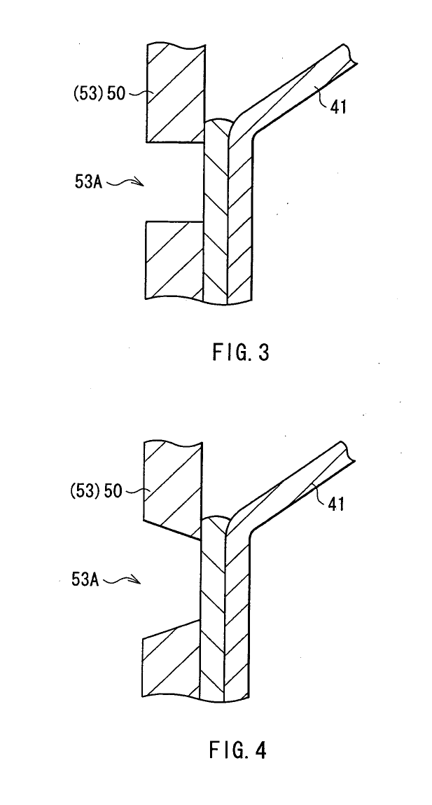

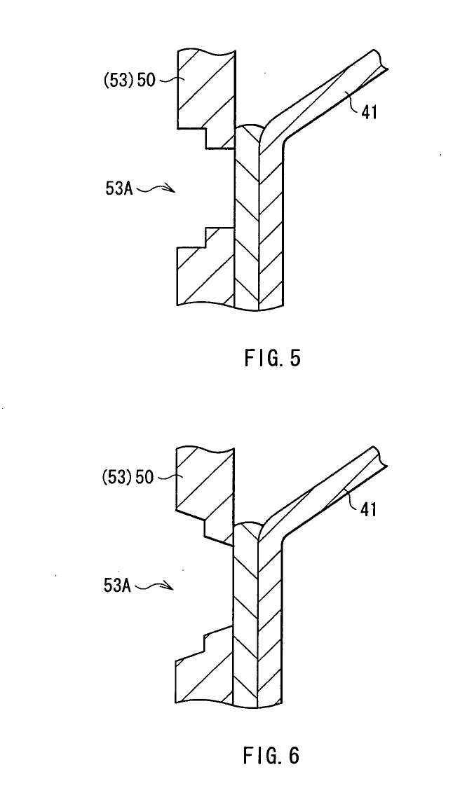

The light accommodation section 53A is configured as, for example, a through-hole penetrating through the housing 53 as illustrated in FIG. 3, 4, 5 or 6. At that time, the through-hole has, for example, a cylindrical shape as illustrated in FIG. 3. For example, an inside of the through-hole may be horizontally straight as illustrated in FIG. 3, may be tapered as illustrated in FIG. 4, or may be step-like as illustrated in FIG. 5. Moreover, for example, the inside of the through-hole may be tapered and step-like as illustrated in FIG. 6.

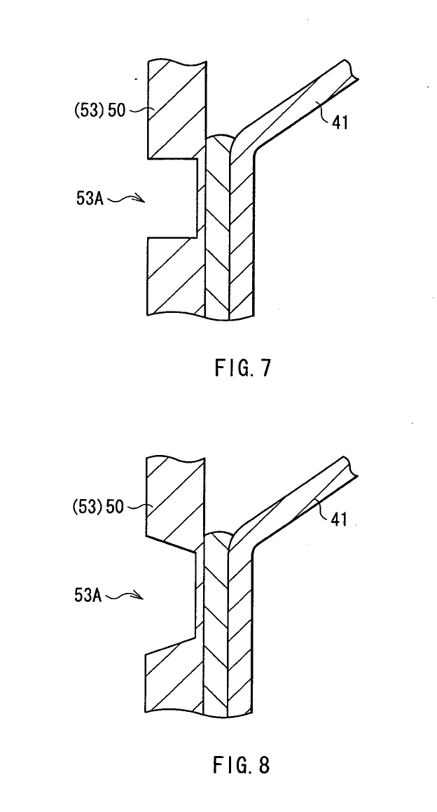

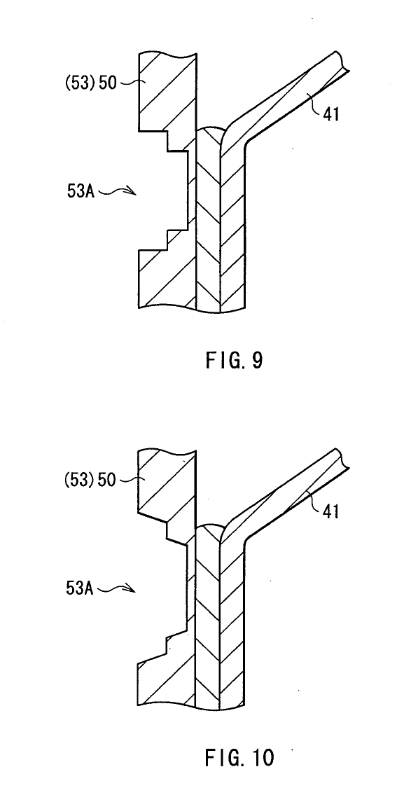

The light accommodation section 53A may have a structure other than the above-mentioned through-hole. For example, the light accommodation section 53A may have a structure where a depression is formed in an outer circumferential surface of the housing 53, and part of the housing 53 is left on a bottom of the depression, as illustrated in FIG. 7, 8, 9 or 10. In such a case, for example, an inside (side face) of the depression may be horizontally straight as illustrated in FIG. 7, may be tapered as illustrated in FIG. 8, or may be step-like as illustrated in FIG. 9. Moreover, for example, the inside (side face) of the depression may be tapered and step-like as illustrated in FIG. 10.

In the case that multiple light accommodation sections 53A are formed in the housing 53, the light accommodation sections 53A in the housing 53 are formed in, for example, n-fold, rotationally symmetric positions (n is a positive integer such as 2, 3 or 4). For example, in the case that two light accommodation sections 53A are formed in the housing 53, the two light accommodation sections 53A are formed in positions opposed to each other with respect to a central axis of the support substrate 11.

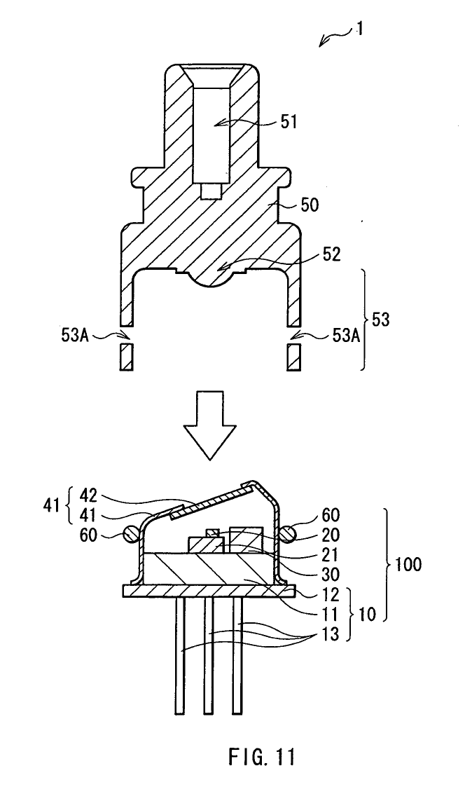

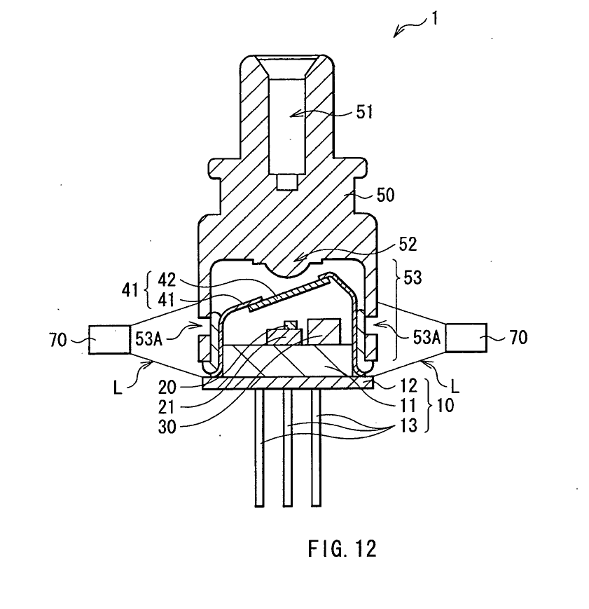

The light transmitter device 1 having such a configuration may be manufactured, for example, in the following way. FIGS. 11 and 12 schematically show a manufacturing process of the light transmitter device 1. First, the stem 10, the light emitting element 20, the light receiving element 30, the cap 40 and the lens receptacle 50 are prepared, and then the light emitting element 20 and the light receiving element 30 are mounted on a top of the support substrate 11, and the light emitting element 20 and the light receiving element 30 are sealed by the cap 40. In this way, first, an intermediate component 100 is prepared (FIG. 11).

Next, UV curing resin 60 is adhered to a circumferential surface of the cap 40 (side face of the cylindrical portion 41) (FIG. 11). At that time, the UV curing resin 60 is preferably adhered in a manner of revolving around the circumferential surface of the cap 40. A material of the UV curing resin 60 is preferably cured not only by UV light but also by heat.

Next, the lens receptacle 50 is fitted with the cap 40 such that the UV curing resin 60 enters a gap between the circumferential surface of the cap 40 and the housing 53 (FIG. 11). At that time, the UV curing resin 60 is pushed by the housing 53 and thus enters a gap formed between an end of the housing 53 (a lower end of the lens receptacle 50) and the cap 40 or the support substrate 11. When the housing 53 reaches a region near the flange 12B, the UV curing resin 60 penetrates deep into the gap formed between the housing 53 and the cap 40 or the support substrate 11 up to a region opposed to the light accommodation section 53A. At that time, in the case that the light accommodation section 53A is configured of a through-hole, the UV curing resin 60 is exposed on the inside of the through-hole.

Next, a UV light generator 70 is disposed near the housing 53, and the UV curing resin 60 is irradiated with UV light and thus the resin 60 is cured. Thus, the housing 53 is adhered to the circumferential surface of the cap 40 or the support substrate 11, so that temporary fixing is completed. At that time, the UV curing resin 60 is largely cured at two portions in total of a portion opposed to the light accommodation section 53A as a region having high light transmittance of the housing 53, and a portion exposed to the outside near the housing 53.

Next, alignment of the lens receptacle 50 is performed so that when an optical fiber is mounted in the sleeve 51, an end face of the optical fiber is disposed at a place corresponding to a focal distance of the lens 52. Next, a heat generator (not illustrated) is disposed near the housing 53 to apply heat to the UV curing resin 60, so that the UV curing resin 60 as a whole is cured. Thus, the housing 53 is securely adhered to the circumferential surface of the cap 40 or the support substrate 11, so that permanent fixing is completed. In this way, the light transmitter device 1 of the embodiment is manufactured.

In the light transmitter device 1 of the embodiment, when an electric signal is externally inputted, the electric signal is converted into an optical signal by the light emitting element 20, and laser light is outputted to the lens 52. The outputted laser light is focused by the lens 52, and thus enters into an end face of the optical fiber, and then transmitted through the optical fiber. In this way, light transmission is performed.

In this embodiment, the light accommodation section 53A, which has a large light accommodation, is provided in a part of the housing 53 of the lens receptacle 50. Thus, in the case that uncured UV curing resin 60 is irradiated with light from the outside during a manufacturing process, a portion corresponding to the light accommodation section 53A of the uncured UV curing resin 60, and a portion exposed to the outside of the uncured UV curing resin 60 may be efficiently irradiated with external light. As a result, temporary fixing may be promptly finished, and fluctuation of the lens receptacle 50 may be suppressed, while reduction in throughput is minimized.

In addition, in the embodiment, the lens receptacle 50 is fitted with the cap 40 such that the UV curing resin 60 enters a gap between the circumferential surface of the cap 40 and the housing 53 during a manufacturing process. Thus, the UV curing resin 60 can penetrate deep into the gap without using the capillary action. In the embodiment, since the UV curing resin 60 is adhered to the circumferential surface of the cap 40, viscosity of the UV curing resin 60 is high compared with viscosity of a UV curing resin in the case of using the capillary action. Therefore, even if the UV light L is not irradiated for a long time, the UV curing resin 60 may be cured over a wide range, and consequently fluctuation may be suppressed, while reduction in throughput is minimized.

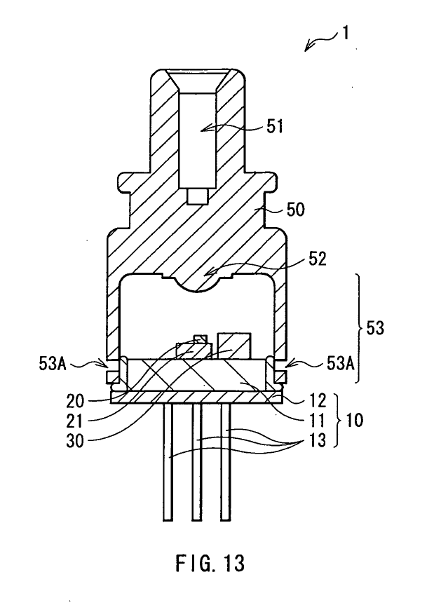

In another embodiment, the light transmission window 42 has a function of a half mirror. However, in the case that the half mirror is unnecessary, for example, in the case that light outputted from the light emitting element 20 may be directly entered into the light receiving element 30, the half mirror function may be omitted. In the case that the cap 40 is unnecessary, the cap 40 may be omitted, for example, as illustrated in FIG. 13. In such a case, the side face 11A of the support substrate 11 is fitted in the housing 53 of the lens receptacle 50.

A light transmitter device according to this embodiment may be manufactured, for example, in the following way. First, the stem 10, the light emitting element 20, the light receiving element 30, and the lens receptacle 50 are prepared, and then the light emitting element 20 and the light receiving element 30 are mounted on a top of the support substrate 11. In this way, first, an intermediate component is prepared.

Next, UV curing resin 60 is adhered to the side face 11A of the support substrate 11 (FIG. 11). At that time, the UV curing resin 60 is preferably adhered in a manner of revolving around the side face 11A. A material of the UV curing resin 60 is preferably cured not only by UV light but also by heat.

Next, the lens receptacle 50 is fitted with the cap 40 such that the UV curing resin 60 enters a gap between the side face 11A of the support substrate 11 and the housing 53. At that time, the UV curing resin 60 is pushed by the housing 53 and thus enters a gap formed between an end of the housing 53 (a lower end of the lens receptacle 50) and the support substrate 11. When the housing 53 reaches a region near the flange 12B, the UV curing resin 60 penetrates deep into the gap formed between the housing 53 and the support substrate 11 up to a region opposed to the light accommodation section 53A. At that time, in the case that the light accommodation section 53A is configured of a through-hole, the UV curing resin 60 is exposed on the inside of the through-hole.

Next, a UV light generator 70 is disposed near the housing 53, and the UV curing resin 60 is irradiated with UV light L and thus the resin 60 is cured. Thus, the housing 53 is adhered to the circumferential surface of the cap 40 or the support substrate 11, so that temporary fixing is completed. At that time, the UV curing resin 60 is largely cured at two portions in total of a portion opposed to the light accommodation section 53A as a region having high light accommodation of the housing 53, and a portion exposed to the outside near the housing 53.

Next, alignment of the lens receptacle 50 is performed so that when an optical fiber is mounted in the sleeve 51, an end face of the optical fiber is disposed at a place corresponding to a focal distance of the lens 52. Next, a heat generator (not illustrated) is disposed near the housing 53 to apply heat to the UV curing resin 60, so that the UV curing resin 60 as a whole is cured. Thus, the housing 53 is securely adhered to the circumferential surface of support substrate 11, so that permanent fixing is completed. In this way, the light transmitter device of this embodiment is manufactured.

Even in the light transmitter device of the other embodiment, the light accommodation section 53A, which has a large light accommodation, is provided in a part of the housing 53 of the lens receptacle 50. Thus, in the case that uncured UV curing resin 60 is irradiated with light from the outside during a manufacturing process, a portion corresponding to the light accommodation section 53A of the uncured UV curing resin 60, and a portion exposed to the outside of the uncured UV curing resin 60 may be efficiently irradiated with external light. As a result, temporary fixing may be promptly finished, and fluctuation of the lens receptacle 50 may be suppressed, while reduction in throughput is minimized.

In addition, the lens receptacle 50 is fitted with the support substrate 11 such that the UV curing resin 60 enters a gap between the side face 11A of the support substrate 11 and the housing 53 during a manufacturing process. Thus, the UV curing resin 60 may be allowed to penetrate deep into the gap without using the capillary action. And since the UV curing resin 60 is adhered to the side face 11A of the support substrate 11, viscosity of the UV curing resin 60 is high compared with viscosity of the UV curing resin in the case of using the capillary action. Therefore, even if the UV curing resin 60 is not irradiated with the UV light L for a long time, the UV curing resin 60 may be cured over a wide range, and consequently fluctuation may be suppressed, while reduction in throughput is minimized.

While the invention has been described with the above embodiments, the invention is not limited to these embodiments, and may be variously modified or altered.

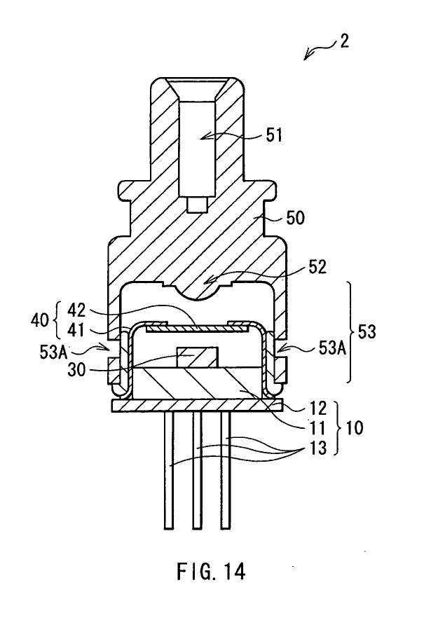

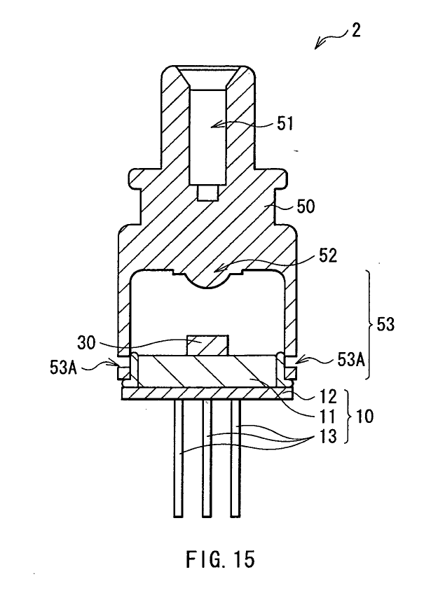

For example, while one embodiment describes a light transmitter device, the invention may be obviously applied to a light receiver device, so-called ROSA (Receiver Optical SubAssembly). For example, as illustrated in FIG. 14, the light accommodation section 53A having a large light accommodation may be provided in part of the housing 53 in a light receiver device 2 formed by removing the light emitting element 20 and the sub-mount 21 from the light transmitter device 1 of the embodiment, and disposing the light receiving element 30 on a central axis of the support substrate 11. Alternatively, for example, as illustrated in FIG. 15, the light accommodation section 53A having a large light accommodation may be provided in part of the housing 53 in a light receiver device 2 from which the cap 40 is omitted. The present application contains subject matter related to that disclosed in Japanese Priority Patent Application JP 2009-192121 filed in the Japan Patent Office on Aug. 21, 2010, the entire content of which is hereby incorporated by reference.

It should be understood by those skilled in the art that various modifications, combinations, sub-combinations, and alterations may occur depending on design requirements and other factors insofar as they are within the scope of the appended claims or the equivalent thereof.

What is claimed is:

1. An optical device comprising:
a housing;
an optical element;
a base structure that supports the optical element and that interfaces with the housing to form a gap section between an outer wall section of the base structure and an inner wall section of the housing;
a resin within the gap section fixing the housing to the base structure; and
a light accommodation section in the housing,
wherein the light accommodation section accommodates a transmittance of light to the resin within the gap section.

2. The optical device of claim 1, wherein the transmittance of light through the light accommodation section is greater than a transmittance of light through the housing.

3. The optical device of claim 3, wherein the ratio of light transmittance through the light accommodation section to that through the housing is at least ten to one.

4. The optical device of claim 1, wherein the base structure comprises a substrate, and an outer wall section of the substrate constitutes the outer wall section of the base structure that forms the gap with the inner wall section of the housing.

5. The optical device of claim 1, wherein the base structure comprises a sealing section that encases the optical element, and an outer wall section of the sealing section constitutes the outer wall section of the base structure that forms the gap portion with the inner wall section of the housing.

6. The optical device of claim 1, wherein the light accommodation section is one of a plurality of light accommodation sections.

7. The optical device of claim 6, wherein the plurality of light accommodation sections are symmetrically and circumferentially displaced along the housing.

8. The optical device of claim 1, wherein the light accommodation section is an open section in the housing.

9. The optical device of claim 8, wherein a light transmission structure is within the open section in the housing.

10. The optical device of claim 8, wherein the open section is a through-hole.

11. The optical device of claim 8, wherein the open section is a depression.

12. The optical device of claim 1, wherein the light accommodation section has a flat side-face.

13. The optical device of claim 1, wherein the light accommodation section has an inclined side-face.

14. The optical device of claim 1, wherein the light accommodation section has a stepped side-face.

15. The optical device of claim 1, wherein the light accommodation section has a stepped inclined side-face.

16. The optical device of claim 1, wherein the light is ultraviolet light, and the resin is an ultraviolet light curing resin.

17. The optical device of claim 16, wherein the resin is also a heat curing resin.

18. An optical device comprising:
a housing;
an optical element;
a base structure that supports the optical element and that interfaces with the housing to form a gap section between an outer wall section of the base structure and an inner wall section of the housing;
a resin within the gap section fixing the housing to the base structure; and
a light accommodation section in the housing,
wherein the light accommodation section and the gap section separately expose the resin to light such that either exposed resin portion or both are irradiated to temporarily fix the housing over the base.

19. A manufacturing method for an optical device comprising:
applying a resin to an outer wall section of a base;
spreading the resin by placing a housing over the base such that the resin fills a gap portion between an inner wall section of the housing and the outer wall section of the base; and
irradiating with light the resin through a light accommodation section in the housing to fix the housing over the base.

20. A manufacturing method for an optical device comprising:
applying a resin to an outer wall section of a base;
spreading the resin by placing a housing over the base such that the resin fills a gap portion between an inner wall section of the housing and the outer wall section of the base;
irradiating with light the resin through either a light accommodation section in a housing, the gap portion, or both to temporarily fix the housing over the base; and
heating the resin to permanently fix the housing over the base.
